(19) United States
(12) Patent Application Publication
(10) Pub. No.: US 2021/0263103 A1
(43) Pub. Date: Aug. 26, 2021

(54) BATTERY LEVEL MANAGEMENT SYSTEM

(71) Applicant: Tymphany Acoustic Technology Limited, Taipei City (TW)

(72) Inventor: Cheng-Yang LIAO, TAIPEI CITY (TW)

(21) Appl. No.: 17/183,811

(22) Filed: Feb. 24, 2021

(30) Foreign Application Priority Data
Feb. 24, 2020 (CN) 202010111795.9

(51) Int. Cl. G01R 31/371; G05B 19/042

(52) U.S. Cl. CPC G01R 31/371; H04Q 2209/40; G05B 2219/25257; G05B 19/042

(57) ABSTRACT

A battery level management system includes a battery module, outputting electric energy, and outputting battery level information according to stored electricity; a control module, receiving the battery level information, and performing encoding according to the battery level information to output a control signal; a constant voltage module, receiving the electric energy to output constant-voltage electric energy, where the control module controls turn-on and turn-off of the constant voltage module through the control signal; and a computing module, receiving the constant-voltage electric energy, and performing decoding according to the constant-voltage electric energy to output the battery level information. The constant voltage module outputs the constant-voltage electric energy with different waveforms according to the control signal, and the computing module obtains the battery level information according to the waveforms of the constant-voltage electric energy.

### CROSS REFERENCE TO RELATED APPLICATIONS

The present application claims priority to Chinese Patent Application No. CN 202010111795.9, which was filed on Feb. 24, 2020, the entire contents of which are hereby incorporated by reference.

### BACKGROUND OF THE INVENTION

### Technical Field

This application relates to a battery level management system, and in particular, to a battery level management system capable of obtaining battery level information according to outputted waveforms.

### Related Art

At present, a container of a wireless earphone often has a battery module for charging the wireless earphone when the wireless earphone is disposed in the container, to improve usage convenience for a user. However, when the user intends to learn a remaining battery level of the container, in the related art, an additional wireless transmission module is disposed in the container, and battery level information is transmitted to a manipulation device, such as a smartphone, of the user in a wireless transmission manner. However, because the container actually only needs to provide containing and charging functions, and does not need the wireless transmission module for paring with the manipulation device, if the additional wireless transmission module is disposed merely for the purpose of providing the battery level information, manufacturing costs are greatly increased and a hardware space is occupied.

In the art, another manner to display the remaining battery level of the container is to use an additional lamp signal module. For example, a plurality of light-emitting diode components, that is, a plurality of light-emitting diodes, are used for displaying different lamp signals for the user to determine the remaining battery level of the container. However, to clearly show the remaining battery level of the container, a relatively large quantity of light-emitting diode components need to be disposed; otherwise, the remaining battery level of the container may only be expressed in a general way. For example, only five light-emitting diode components are used, to express 20%, 40%, 60%, 80%, and 100%, and in this case, the user cannot clearly learn a precise remaining battery level of the container. In addition, the use of the plurality of light-emitting diode components causes the dilemma of high manufacturing costs and occupation of a large hardware space. It may be learned that the use of the additional lamp signal module cannot achieve good technical goals.

Therefore, in the field of battery level management systems, every effort is made to design a battery level management system that can reduce manufacturing costs and provide battery level information easily comprehensible for a user, so as to improve the convenience of using an electronic product and reduce the manufacturing costs of the electronic product.

### SUMMARY

In view of this, this application provides a battery level management system.

This application provides a battery level management system. The battery level management system of this application includes: a battery module, outputting electric energy, and outputting battery level information according to stored electricity; a control module, receiving the battery level information, and performing encoding according to the battery level information to output a control signal; a constant voltage module, receiving the electric energy to output constant-voltage electric energy, where the control module controls turn-on and turn-off of the constant voltage module through the control signal; and a computing module, receiving the constant-voltage electric energy, and performing decoding according to the constant-voltage electric energy to output the battery level information, where the constant voltage module outputs the constant-voltage electric energy with different waveforms according to the control signal, and the computing module obtains the battery level information according to the waveforms of the constant-voltage electric energy.

In an embodiment, the computing module is disposed in a wireless earphone, and the battery module, the control module and the constant voltage module are disposed in a container, where the container is used for accommodating the wireless earphone.

In an embodiment, the battery level management system further includes a transmission module configured to receive the battery level information outputted by the computing module through decoding, and output the information to a display device.

In an embodiment, the transmission module is a wireless transmission module.

In an embodiment, the display device is a hand-held electronic device.

In an embodiment, the waveform of the constant-voltage electric energy is a square wave, and the control signal controls a waveform width of the square wave.

In an embodiment, the waveforms of the constant-voltage electric energy include a trigger waveform, a battery level waveform, and an end waveform.

This application further provides a battery level management method. The battery level management method of this application includes: outputting electric energy of a battery module and battery level information corresponding to stored electricity of the battery module; transmitting the battery level information to a control module, and performing encoding by the control module according to the battery level information to output a control signal; transmitting the electric energy to a constant voltage module, and outputting constant-voltage electric energy through the constant voltage module; transmitting the control signal to the constant voltage module, and controlling turn-on and turn-off of the constant voltage module through the control signal; controlling, according to the turn-on and turn-off of the constant voltage module, the constant-voltage electric energy outputting different waveforms; and transmitting the constant-voltage electric energy to a computing module, and performing decoding by the computing module according to the waveforms of the constant-voltage electric energy to output the battery level information.

Based on the above, according to the battery level management system of this application, convenience of using an electronic product may be improved, and manufacturing costs of the electronic product are reduced.

### BRIEF DESCRIPTION OF THE DRAWINGS

FIG. 1 is a module block diagram of an embodiment of a battery level management system according to this application;

FIG. 2A to FIG. 2C are waveform diagrams of an embodiment of a battery level management system according to this application; and

FIG. 3 is a flowchart of a method of an embodiment of a battery level management system according to this application.

### DETAILED DESCRIPTION

For ease of reading, “up”, “down”, “left”, and “right” are indicated according to the drawings, so as to indicate reference relative positions between components, but are not intended to limit this application.

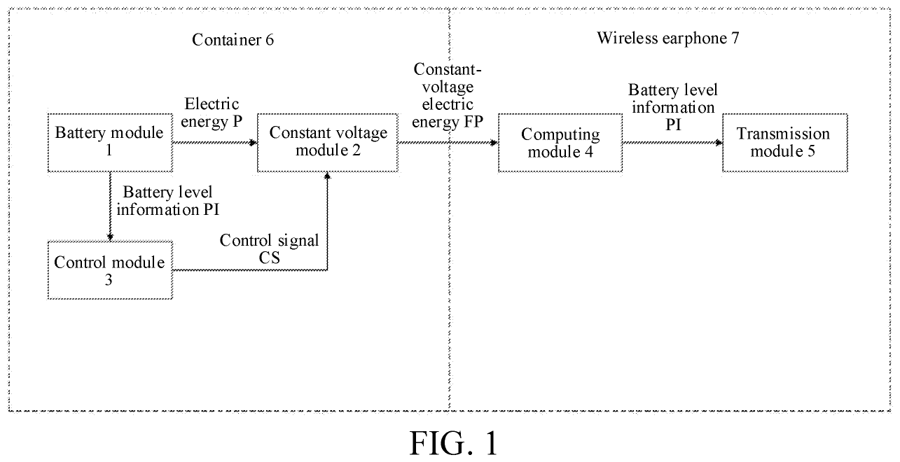

FIG. 1 is a module block diagram of an embodiment of a battery level management system according to this application. The battery level management system of this application may be applied to communication of battery level information between any electronic devices. A wireless earphone and a container thereof are used as an example, but the embodiments of this application are not limited thereto. As shown in FIG. 1, the battery level management system of this application includes a battery module 1, a constant voltage module 2, a control module 3 and a computing module 4, wherein the battery module 1, the constant voltage module 2 and the control module 3 are disposed in a container 6, and the computing module 4 is disposed in a wireless earphone 7.

The battery module 1 is formed by a battery unit that stores and outputs electric energy, and may be formed by a single battery unit or a plurality of battery units. The battery module 1 is configured to store and output electric energy P. When the wireless earphone 7 is accommodated in the container 6, the battery module 1 may output the stored electric energy P to the wireless earphone 7, to charge the wireless earphone 7. In addition, the battery module 1 further provides battery level information PI, where the battery level information PI may be, but is not limited to, a remaining battery level, battery health, or other battery-related information. In this embodiment, the battery level information PI is the remaining battery level, where the remaining battery level may be displayed in the form of a percentage, a customized grade or the like. However, in this embodiment, the battery level information PI is displayed in the form of a percentage.

The constant voltage module 2 receives the electric energy P from the battery module 1, performs constant voltage conversion on the electric energy P, and outputs constant-voltage electric energy FP. When the wireless earphone 7 is accommodated in the container 6, the constant-voltage electric energy FP may charge the wireless earphone 7. In some embodiments, the constant voltage module 2 is a constant voltage device or a functional module disposed in the constant voltage device.

The control module 3 performs encoding according to the battery level information PI of the battery module 1 to output a control signal CS, where the control signal CS is transmitted to the constant voltage module 2 to control turn-on and turn-off of the constant voltage module 2. In other words, the control signal CS is an enable signal of the constant voltage module 2. The control module 3 adjusts, by controlling the constant voltage module 2 to turn on or turn off, waveforms of the constant-voltage electric energy FP outputted by the constant voltage module 2, thereby transmitting the battery level information PI through the waveforms of the constant-voltage electric energy FP. In some embodiments, the control module 3 is a functional module disposed in a microcontroller of the container 6, or a computing module that is disposed independently.

When the constant-voltage electric energy FP is transmitted to the wireless earphone 7, the computing module 4 detects the waveform of the constant-voltage electric energy FP, and decodes the waveform of the constant-voltage electric energy FP, to obtain the battery level information PI from the battery module 1. In this case, the wireless earphone 7 may obtain the battery level information PI from the battery module 1 of the container 6. In some embodiments, the computing module 4 is a functional module disposed in a chip module of the wireless earphone 7, or a computing module that is disposed independently. In some embodiments, the wireless earphone 7 may further transmit, through a transmission module 5, the battery level information PI to a display device (not shown) operated by a user, so that the battery level information PI is clearly provided to the user. The transmission module 5 may be a wired or wireless transmission module, and the display device operated by the user may be, but is not limited to, a hand-held electronic device or another electronic device that may provide information for the user.

When the user puts the wireless earphone 7 into the container 6, the constant voltage module 2 outputs the constant-voltage electric energy FP with a specific waveform to the wireless earphone 7 according to the control signal CS of the control module 3, where the specific waveform of the constant-voltage electric energy FP represents the battery level information PI. When the wireless earphone 7 receives the constant-voltage electric energy FP with the specific waveform, the computing module 4 disposed in the wireless earphone 7 detects the waveform of the constant-voltage electric energy FP and performs decoding, thereby obtaining the battery level information PI. In this case, the wireless earphone 7 has obtained the battery level information PI of the container 6. When the wireless earphone 7 is connected to the display device operated by the user, the battery level information PI of the container 6 may be transmitted to the display device operated by the user, and the user learns a battery level state of the container 6.

It may be learned that, in the battery level management system of this application, it is unnecessary to dispose an additional transmission module in the container to transmit the battery level information of the container. The battery level information of the container can be transmitted only by using original modules related to electric energy transmission, thus greatly reducing manufacturing costs of the product. In addition, in the battery level management system of this application, the outputted waveforms are encoded merely by using the existing enable signal of the constant voltage module, so that the battery level information of the container is transmitted by using the waveforms of the constant-voltage electric energy. Therefore, computing load in the product may further be greatly reduced, thus improving the value of the overall product.

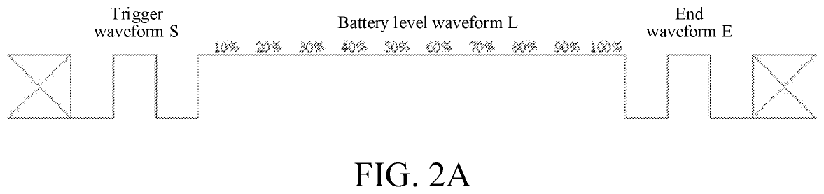

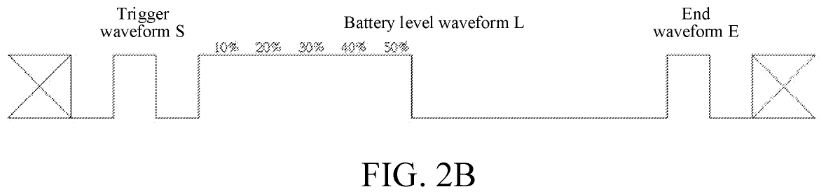

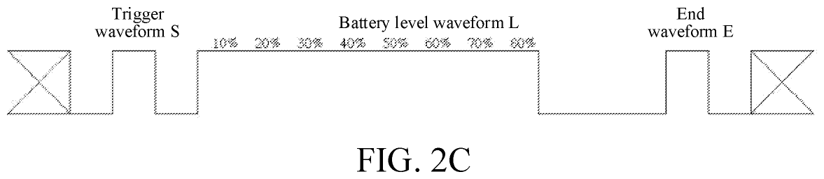

FIG. 2A to FIG. 2C are waveform diagrams of an embodiment of a battery level management system according to this application. As shown in FIG. 2A to FIG. 2C, the waveforms of the constant-voltage electric energy FP in this application are square waves including a trigger waveform S, a battery level waveform L and an end waveform E according to an output sequence.

The trigger waveform S is used for describing a start signal representing the specific waveform of the constant-voltage electric energy FP of the battery level information PI. When the computing module 4 detects the trigger waveform S through decoding, it indicates that the specific waveform of the constant-voltage electric energy FP of the battery level information PI has been transmitted by the constant voltage module 2.

The battery level waveform L is used for representing the battery level information PI. In this embodiment, the battery level waveform L is used for representing the remaining battery level of the battery module, and in this embodiment, the remaining battery level is displayed in the form of a percentage. After the computing module 4 detects the trigger waveform S through decoding, it is determined that a next received waveform is the battery level waveform L, that is, a waveform describing the remaining battery level of the battery module. Therefore, the computing module 4 may detect the remaining battery level of the battery module through decoding according to the battery level waveform L.

The end waveform E is used for describing a stop signal representing the specific waveform of the constant-voltage electric energy FP of the battery level information PI. When the computing module 4 detects the end waveform E through decoding, it is determined that the specific waveform representing the constant-voltage electric energy FP of the battery level information PI has been ended, and the computing module 4 stops determining a subsequently detected waveform of the constant-voltage electric energy FP as the specific waveform representing the battery level information PI.

When the control signal CS controls the turn-on and turn-off of the constant voltage module 2, the waveform outputted by the constant-voltage electric energy FP of the constant voltage module 2 is switched to a high level or a low level corresponding to the turn-on and turn-off of the constant voltage module 2, that is, when the control signal CS controls the constant voltage module 2 to turn on, the outputted waveform of the constant-voltage electric energy FP is in the high level. Conversely, when the control signal CS controls the constant voltage module 2 to turn off, the outputted waveform of the constant-voltage electric energy FP is in the low level. In this way, the control signal CS may control a waveform width of the outputted waveform of the constant-voltage electric energy FP.

Still referring to FIG. 2A to FIG. 2C, in the battery level management system of this application, the trigger waveform S and the end waveform E have specific waveform widths for the computing module 4 to determine the start and end of the specific waveform representing the battery level information PI. When a rising edge of a square wave signal is detected, the computing module 4 calculates a waveform width of the square wave signal, and when a falling edge of the square wave signal is detected, the computing module 4 stops calculating the waveform width of the square wave signal. If the calculated waveform width conforms to a specific waveform width of the trigger waveform S, the square wave signal is determined to be the trigger waveform S. Similarly, if the calculated waveform width conforms to a specific waveform width of the end waveform E, the square wave signal is determined to be the end waveform E.

In this embodiment, after determining that a next received waveform is the battery level waveform L, the computing module 4 starts to calculate a waveform width upon detection of a rising edge of a next square waveform, and the computing module 4 stops calculating the waveform width of the square wave signal upon detection of a falling edge of the square wave signal. As shown in FIG. 2A to FIG. 2C, different waveform widths indicate different percentages of the remaining battery level. After the computing module 4 obtains the waveform width of the battery level waveform L, the calculated waveform width is compared with a comparison table stored in advance, to obtain the remaining battery level of the container 6.

To make the trigger waveform S and the end waveform E have specific waveform widths, in some embodiments, the waveform width of the battery level waveform L is different from those of the trigger waveform S and the end waveform E, that is, regardless of the battery level information PI represented by the battery level waveform L, the battery level waveform L is different from the trigger waveform S and the end waveform E, so as to avoid misjudgment by the computing module 4.

In some embodiments, the battery level waveform L may be formed by a plurality of square waveforms, but not a single square waveform. For example, the battery level waveform L may be formed by a plurality of square waves with the same specific waveform width, and the computing module 4 may determine the battery level information PI by calculating a quantity of the square waves with the same specific waveform width.

In some embodiments, the battery level waveform L may alternatively be formed by a plurality of square waves with different specific waveform widths, and the computing module 4 may determine the battery level information PI by calculating specific permutation and combination formed by the square waves.

In some embodiments, the computing module 4 may alternatively sample the battery level waveform L according to a customized time interval, the battery level waveform L is cut, according to the customized time interval, into waveform combinations each including a plurality of square waves with different or the same waveform widths, and the computing module 4 may determine the battery level information PI through the waveform combination.

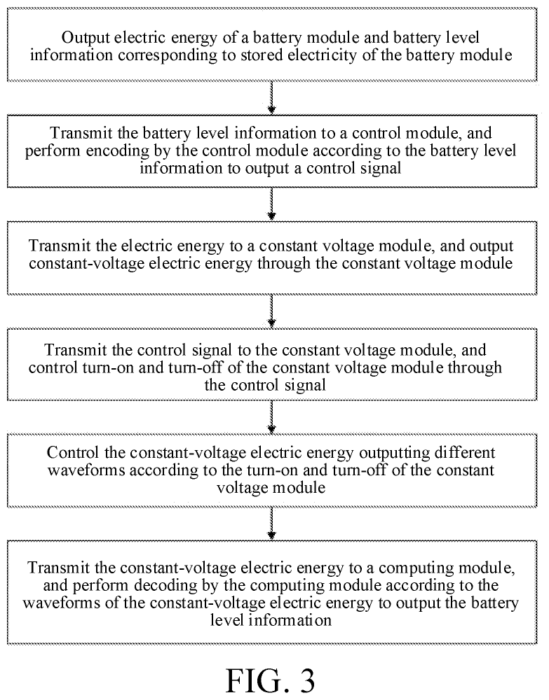

FIG. 3 is a flowchart of a method of an embodiment of a battery level management method according to this application. As shown in the figure, this application further provides a battery level management method, including the following steps:
outputting electric energy of a battery module and battery level information corresponding to stored electricity of the battery module;
transmitting the battery level information to a control module, and performing encoding by the control module encoding according to the battery level information to output a control signal;
transmitting the electric energy to a constant voltage module, and outputting constant-voltage electric energy through the constant voltage module;
transmitting the control signal to the constant voltage module, and controlling turn-on and turn-off of the constant voltage module through the control signal;
controlling, according to the turn-on and turn-off of the constant voltage module, the constant-voltage electric energy outputting different waveforms; and
transmitting the constant-voltage electric energy to a computing module, and performing decoding by the computing module according to the waveforms of the constant-voltage electric energy to output the battery level information.

By using the battery level management method of this application, manufacturing costs and computing load of the product may be effectively reduced, thereby increasing product value.

Based on the above, according to a battery level management system of this application, it is unnecessary to dispose an additional transmission module in the container to transmit the battery level information of the container, thus greatly reducing manufacturing costs of the product. In addition, in the battery level management system of this application, outputted waveforms are encoded merely by using the existing enable signal of the constant voltage module, so that the battery level information of the container is transmitted by using the waveforms of the constant-voltage electric energy. Therefore, computing load in the product may further be greatly reduced, and value of the overall product is improved.

Although this application is disclosed with reference to the above embodiments, the embodiments are not intended to limit this application. A person skilled in the art may make variations and modifications without departing from the spirit and scope of this application. Therefore, the protection scope of this application should be subject to the scope defined by the appended claims.

What is claimed is:

1. A battery level management system, comprising:
a battery module outputting electric energy and outputting battery level information according to stored electricity;
a control module receiving the battery level information and performing encoding according to the battery level information to output a control signal;
a constant voltage module receiving the electric energy to output constant-voltage electric energy, wherein the control module controls turn-on and turn-off of the constant voltage module through the control signal; and
a computing module receiving the constant-voltage electric energy and performing decoding according to the constant-voltage electric energy to output the battery level information,
wherein the constant voltage module outputs the constant-voltage electric energy with different waveforms according to the control signal, and the computing module obtains the battery level information according to the waveforms of the constant-voltage electric energy.

2. The battery level management system according to claim 1, wherein the computing module is disposed in a wireless earphone, and the battery module, the control module and the constant voltage module are disposed in a container, and
wherein the container is used for accommodating the wireless earphone.

3. The battery level management system according to claim 1, wherein the battery level management system further comprises a transmission module configured to receive the battery level information outputted by the computing module through decoding and output the battery level information.

4. The battery level management system according to claim 3, wherein the transmission module is a wireless transmission module.

5. The battery level management system according to claim 1, wherein the waveform of the constant-voltage electric energy is a square wave and the control signal controls a waveform width of the square wave.

6. The battery level management system according to claim 5, wherein the waveforms of the constant-voltage electric energy comprise:
a trigger waveform;
a battery level waveform; and
an end waveform.

7. A battery level management method, comprising:
outputting electric energy of a battery module and battery level information corresponding to stored electricity of the battery module;
transmitting the battery level information to a control module and performing encoding by the control module according to the battery level information to output a control signal;
transmitting the electric energy to a constant voltage module and outputting constant-voltage electric energy through the constant voltage module;
transmitting the control signal to the constant voltage module and controlling turn-on and turn-off of the constant voltage module through the control signal;
controlling, according to the turn-on and turn-off of the constant voltage module, the constant-voltage electric energy outputting different waveforms; and
transmitting the constant-voltage electric energy to a computing module and performing decoding by the computing module according to the waveforms of the constant-voltage electric energy to output the battery level information.
